(19) United States
(12) Patent Application Publication
(10) Pub. No.: US 2024/0038531 A1
(43) Pub. Date: Feb. 1, 2024

(54) SUBSTRATE MODIFICATION FOR SUPERLATTICE CRITICAL THICKNESS IMPROVEMENT

(71) Applicant: Applied Materials, Inc., Santa Clara, CA (US)

(72) Inventors: Thomas KIRSCHENHEITER, Tempe, AZ (US); John TOLLE, Gilbert, AZ (US); Abhishek DUBE, Fremont, CA (US); Maribel MALDONADO-GARCIA, Valle de Santiago (MX)

(21) Appl. No.: 18/098,547

(22) Filed: Jan. 18, 2023

Related U.S. Application Data
(60) Provisional application No. 63/392,597, filed on Jul. 27, 2022.

(51) Int. Cl. H01L 21/02; H01L 21/304; H10B 12/00

(52) U.S. Cl. CPC H01L 21/02532; H01L 21/02507; H01L 21/0245; H01L 21/0206; H01L 21/02381; H01L 21/0262; H01L 21/304; H10B 12/02; H10B 12/30

(57) ABSTRACT

A method and apparatus for forming strain relaxed buffers that may be used in semiconductor devices incorporating superlattice structures are provided. The method includes epitaxially depositing a first silicon germanium layer over the substrate. The first silicon germanium layer has a first surface that contacts a frontside surface of the substrate and a second surface opposite the first surface. The first silicon germanium layer has a first thickness and a germanium concentration gradient that increases from the first surface to the second surface. The method further includes epitaxially depositing a silicon germanium capping layer on the first silicon germanium layer. The silicon germanium capping layer has a second thickness and a substantially uniform germanium concentration that is equal to, substantially equal to, or greater than a maximum germanium concentration of the germanium concentration gradient.

### CROSS-REFERENCE TO RELATED APPLICATIONS

This application claims the benefit of U.S. Provisional Patent Application Ser. No. 63/392,597, filed Jul. 27, 2022, which is incorporated by reference herein in its entirety.

### TECHNICAL FIELD

The present disclosure relates to semiconductor devices and methods for manufacturing semiconductor devices. More particularly, the present disclosure relates to strain relaxed buffers (SRBs) that may be used in semiconductor devices incorporating superlattice structures and methods for manufacturing the same.

### BACKGROUND

Group III-V and Group IV compound films are generally formed by heteroepitaxy, a form of epitaxy. In epitaxy, a monocrystalline film is deposited on a monocrystalline substrate from gaseous or liquid precursors. During deposition, the substrate acts as a seed crystal, the deposited film takes on a lattice structure and orientation identical to those of the substrate. The deposited film is typically referred to as an epitaxial film or epitaxial layer. In heteroepitaxy, the epitaxial film and the substrate typically include different materials having different properties, for example, lattice constant and thermal expansion coefficient. The differences in properties introduce defects in the epitaxial film and may even cause the substrates to crack when growing the epitaxial film. For example, when growing silicon germanium (SiGe) material on a silicon substrate, mechanical stress and thermal stress may be generated due to a difference in lattice constants and thermal expansion coefficients causing the silicon substrate to bow and the epitaxial SiGe material and even the silicon substrate to crack.

One approach to reducing the defect density involves growing thick SRB layers on the substrate. These thick SRB layers that may be targeted for strain relaxation can be expensive to grow. Others have attempted to grow dissimilar materials that have a tendency to relax quickly on the substrate of choice, or otherwise grow thicker films that eventually relax due to accumulated strain. However, these processes often take a long time to complete and involve costly materials.

Thus, there is a need for thinner SRB layers that reduce defect density while reducing processing times and costs.

### SUMMARY

The present disclosure relates to semiconductor devices and methods for manufacturing semiconductor devices. More particularly, the present disclosure relates to SRB layers that may be used in semiconductor devices incorporating superlattice structures and methods for manufacturing the same.

In one aspect, a method of forming a strain relaxed buffer (SRB) on a substrate is provided. The method includes epitaxially depositing a first silicon germanium layer over the substrate. The first silicon germanium layer has a first surface that contacts a frontside surface of the substrate and a second surface opposite the first surface. The first silicon germanium layer has a first thickness and a germanium concentration gradient that increases from the first surface to the second surface. The method further includes epitaxially depositing a silicon germanium capping layer on the first silicon germanium layer. The silicon germanium capping layer has a second thickness and a substantially uniform germanium concentration that is equal to, substantially equal to, or greater than a maximum germanium concentration of the germanium concentration gradient.

Implementations may include one or more of the following. The first thickness is in a range from about 2000 nm to about 2500 nm and the germanium concentration gradient increases from 0 at % adjacent to an interface with the substrate to the maximum germanium concentration in a range from about 10 at % to about 15 at %. The second thickness is in a range from about 1000 nm to about 1200 nm and the substantially uniform germanium concentration is substantially equal to, equal to, or greater than the maximum germanium concentration of the first silicon germanium layer. The germanium concentration gradient increases from a first germanium concentration in a range from about 0 at % to about 2 at % of germanium to a second germanium concentration in range from about 10 at % to about 15 at %. The substrate comprises silicon. The method further includes polishing the silicon germanium capping layer to reduce the second thickness to a third thickness. After polishing the silicon germanium capping layer, the silicon germanium capping layer has a top surface having a root mean square (RMS) roughness of 5 Å or less. The method further includes exposing the silicon germanium capping layer to a wet clean process after polishing the silicon germanium capping layer. Epitaxially depositing the first silicon germanium layer over the substrate comprises increasing a flow rate of a germanium source gas to form the germanium concentration gradient that increases from the first surface to the second surface.

In another aspect, a device structure is provided. The device structure includes a substrate. The device structure further includes a strain relaxed buffer layer formed on the substrate. The strain relaxed buffer layer includes a first silicon germanium layer having a first surface that contacts a frontside surface of the substrate and a second surface opposite the first surface. The first silicon germanium layer has a first thickness and a germanium concentration gradient that increases from the first surface to the second surface. The strain relaxed buffer layer further includes a silicon germanium capping layer that contacts the second surface of the first silicon germanium layer. The silicon germanium capping layer has a second thickness and a substantially uniform germanium concentration that is equal to, substantially equal to, or greater than a maximum germanium concentration of the germanium concentration gradient. The device structure further includes a superlattice structure formed on the strain relaxed buffer layer. The superlattice structure includes a silicon germanium spacer layer and a silicon channel layer, wherein the silicon germanium spacer layer and the silicon channel layer are disposed in an alternating stacked arrangement.

Implementations may include one or more of the following. The first thickness is in a range from about 2000 nm to about 2500 nm and the germanium concentration gradient increases from 0 at % adjacent to an interface with the substrate to a maximum germanium concentration in a range from about 10 at % to about 15 at %. The second thickness is in a range from about 1000 nm to about 1200 nm and the substantially uniform germanium concentration is substantially equal to, equal to, or greater than the maximum germanium concentration of the first silicon germanium layer. The germanium concentration gradient increases from a first germanium concentration in a range from about 0 at % to about 2 at % of germanium to a second germanium concentration in range from about 10 at % to about 15 at %. The device structure is a dynamic random-access memory (DRAM) device. The silicon germanium capping layer has a top surface having a root mean square (RMS) roughness of 5 Å or less. The device structure further includes a plurality of trenches formed through the strain relaxed buffer layer and the superlattice structure. The device structure further includes one or more etch-holes formed through the strained relaxed buffer and the superlattice structure. The one or more etch-holes are filled with one or more of a poly material and an oxide material. The poly material is a polycrystalline silicon material and the oxide material is silicon oxide. The substrate comprises silicon.

In yet another aspect, a method of forming a semiconductor device is provided. The method includes epitaxially depositing a strain relaxed buffer layer over a substrate, in a first processing chamber. Epitaxially depositing the strain relaxed buffer layer includes epitaxially depositing a first silicon germanium layer over the substrate. The first silicon germanium layer has a first thickness and a germanium concentration gradient that increases from a first surface to a second surface of the first silicon germanium layer. Epitaxially depositing the strain relaxed buffer layer further includes epitaxially depositing a silicon germanium capping layer on the first silicon germanium layer. The silicon germanium capping layer has a second thickness and a substantially uniform germanium concentration that is equal to, substantially equal to, or greater than a maximum germanium concentration of the germanium concentration gradient. The method further includes transferring the substrate to a second processing chamber positioned ex-situ to an integrated processing system. The method further includes polishing the silicon germanium capping layer to reduce the second thickness to a third thickness in the second processing chamber. The method further includes transferring the substrate to a third processing chamber positioned ex-situ to the integrated processing system. The method further includes exposing the silicon germanium capping layer to a wet clean process in the third processing chamber after polishing the silicon germanium capping layer. The method further includes transferring the substrate to a first processing chamber of the integrated processing system. The method further includes exposing the substrate to a dry clean process in the first processing chamber of the integrated processing system using a remote plasma source to generate an etchant species from a fluorine-containing precursor and a hydrogen-containing precursor. The method further includes transferring the substrate to a second processing chamber of the integrated processing system. The method further includes epitaxially depositing a superlattice structure on the strain relaxed buffer layer in the second processing chamber of the integrated processing system.

Implementations may include one or more of the following. The first thickness is in a range from about 2000 nm to about 2500 nm and the germanium concentration gradient increases from 0 at % adjacent to an interface with the substrate to a maximum germanium concentration in a range from about 10 at % to about 15 at %. The second thickness is in a range from about 1000 nm to about 1200 nm and the substantially uniform germanium concentration is substantially equal to, equal to, or greater than the maximum germanium concentration of the first silicon germanium layer. The germanium concentration gradient increases from a first germanium concentration in a range from about 0 at % to about 2 at % of germanium to a second germanium concentration in range from about 10 at % to about 15 at %. The substrate comprises silicon.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above-recited features of the present disclosure can be understood in detail, a more particular description of the aspects, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 illustrates a schematic cross-sectional view of a deposition chamber that may be used for forming SRB layers in accordance with one or more embodiments of the present disclosure.

FIG. 2 illustrates an exemplary flow chart in accordance with one or more embodiments of the present disclosure.

FIGS. 3A-3F illustrate cross-sectional views of various stages of manufacturing a semiconductor device structure in accordance with one or more embodiments of the present disclosure.

FIG. 4 illustrates a partial device structure of a memory device in accordance with one or more embodiments of the present disclosure.

FIG. 5 illustrates a plan view of a cluster tool in accordance with one or more embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Superlattice structures may be utilized in the fabrication of devices that form integrated circuits. These superlattice structures incorporate films, for example, multiple stacks of silicon and silicon germanium films, which possess varying characteristics depending upon the particular application for which the film is being deposited. One characteristic that is key to control for certain applications is film stress. For example, in some applications, it may be appropriate to form a silicon germanium film having a higher stress (as compared to an underlying silicon substrate) so as to improve electron mobility through the silicon. Such improved electron mobility increases the speed of the device structure.

In other applications, it may be appropriate to form a silicon germanium film having a lower stress (as compared to an underlying silicon substrate) so as to minimize dislocation of the layer from, for example, the underlying substrate or to minimize the formation of dislocations in the substrate itself. Such dislocations are detrimental to device functionality as they scatter electron/hole motion and/or enhance diffusion where it is not appropriate to do so. In addition as the number of film stacks in the superlattice structure increases, additional mechanical stress and thermal stress may be generated due to a difference in lattice constants and thermal expansion coefficients causing the silicon substrate to bow and the epitaxial SiGe material of the superlattice structure and even the silicon substrate to crack.

Various embodiments described herein provide a strain relaxed buffer (SRB) or other similar virtual/compliant substrate to enable increased number of unit cells, or additional degrees of composition/film thickness freedom. In some embodiments, the SRB/virtual/compliant substrate will also provide a reduction in defects of the 3D dynamic random-access memory (DRAM) superlattice itself. The additional degrees of freedom for 3D DRAM superlattice processing allows for simultaneous optimization of cell count and post-processing integration, for example, etch selectivity. One parameter of 3D DRAM superlattice processing is the maximum cell count achieved without defects. By using a pre-strain compensation or compliant substrate as described herein it is possible to correct the SiGe lattice mismatch underneath the superlattice thus increasing the effective cell count.

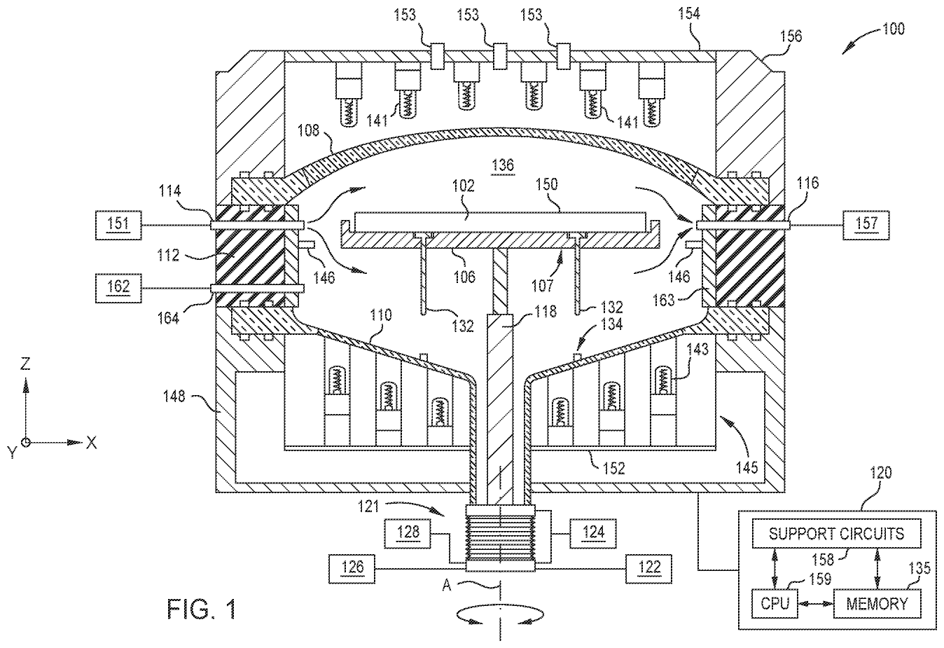

FIG. 1 illustrates a schematic cross-sectional view of a deposition chamber 100 that may be used for forming a strain relaxed buffer in accordance with one or more embodiments of the present disclosure. The deposition chamber 100 may be utilized to grow an epitaxial film on a substrate, such as the substrate 102. The deposition chamber 100 creates a cross-flow of precursors across the top surface 150 of the substrate 102.

The deposition chamber 100 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper dome 108, a lower dome 110, a plurality of upper lamps 141, and a plurality of lower lamps 143. As shown, a controller 120 is in communication with the deposition chamber 100 and is used to control processes, such as those described herein. The controller 120 may include memory 135, a CPU 159, and support circuits 158. The substrate support 106 is disposed between the upper dome 108 and the lower dome 110. The plurality of upper lamps 141 are disposed between the upper dome 108 and a lid 154. The lid 154 includes a plurality of sensors 153 disposed therein for measuring the temperature within the deposition chamber 100. The plurality of lower lamps 143 are disposed between the lower dome 110 and a floor 152. The plurality of lower lamps 143 form a lower lamp assembly 145.

A processing volume 136 is defined between the upper dome 108 and the lower dome 110. The processing volume 136 has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment of the shaft 118 and/or the substrate support 106 within the processing volume 136. The motion assembly 121 includes a rotary actuator 122 that rotates the shaft 118 and/or the substrate support 106 about a longitudinal axis A of the deposition chamber 100. The motion assembly 121 further includes a vertical actuator 124 to lift and lower the substrate support 106 in the z-direction. The motion assembly 121 includes a tilt adjustment device 126 that is used to adjust the planar orientation of the substrate support 106 and a lateral adjustment device 128 that is used to adjust the position of the shaft 118 and the substrate support 106 side to side within the processing volume 136.

The substrate support 106 may include lift pin holes 107 disposed therein. The lift pin holes 107 are sized to accommodate a lift pin 132 for lifting of the substrate 102 from the substrate support 106 either before or after a deposition process is performed. The lift pins 132 may rest on lift pin stops 134 when the substrate support 106 is lowered from a processing position to a transfer position.

The flow module 112 includes a plurality of process gas inlets 114, a plurality of purge gas inlets 164, and one or more exhaust gas outlets 116. The plurality of process gas inlets 114 and the plurality of purge gas inlets 164 are disposed on the opposite side of the flow module 112 from the one or more exhaust gas outlets 116. One or more flow guides 146 are disposed below the plurality of process gas inlets 114 and the one or more exhaust gas outlets 116. The flow guide 146 is disposed above the purge gas inlets 164. A liner 163 is disposed on the inner surface of the flow module 112 and protects the flow module 112 from reactive gases used during deposition processes. The process gas inlets 114 and the purge gas inlets 164 are positioned to flow a gas parallel to the top surface 150 of a substrate 102 disposed within the processing volume 136. The process gas inlets 114 are fluidly connected to a process gas source 151. The purge gas inlets 164 are fluidly connected to a purge gas source 162. The one or more exhaust gas outlets 116 are fluidly connected to an exhaust pump 157. Each of the process gas source 151 and the purge gas source 162 may be configured to supply one or more precursors or process gases into the processing volume 136.

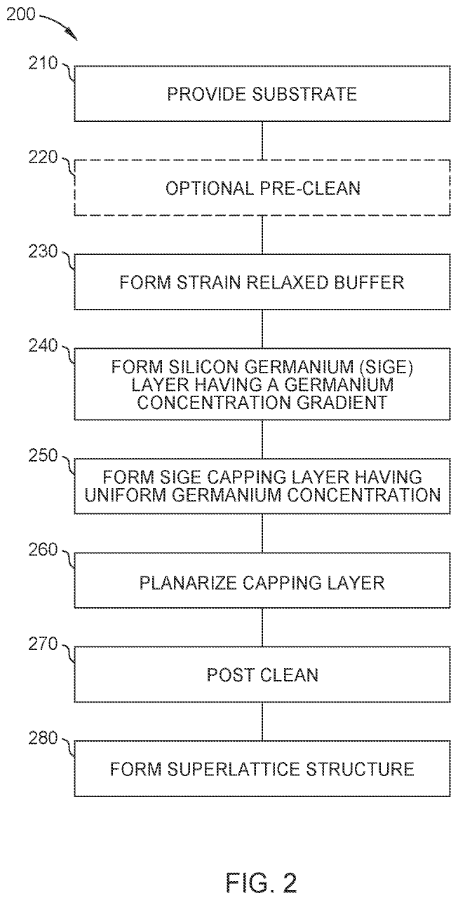

FIG. 2 illustrates an exemplary flow chart of a method 200 in accordance with one or more embodiments of the present disclosure. The method 200 may be part of a multi-operation fabrication process of a semiconductor device incorporating a superlattice structure, for example, a DRAM device or a gate-all-around (GAA) transistor device. The method 200 may be used to form a strain relaxed buffer in accordance with one or more embodiments of the present disclosure.

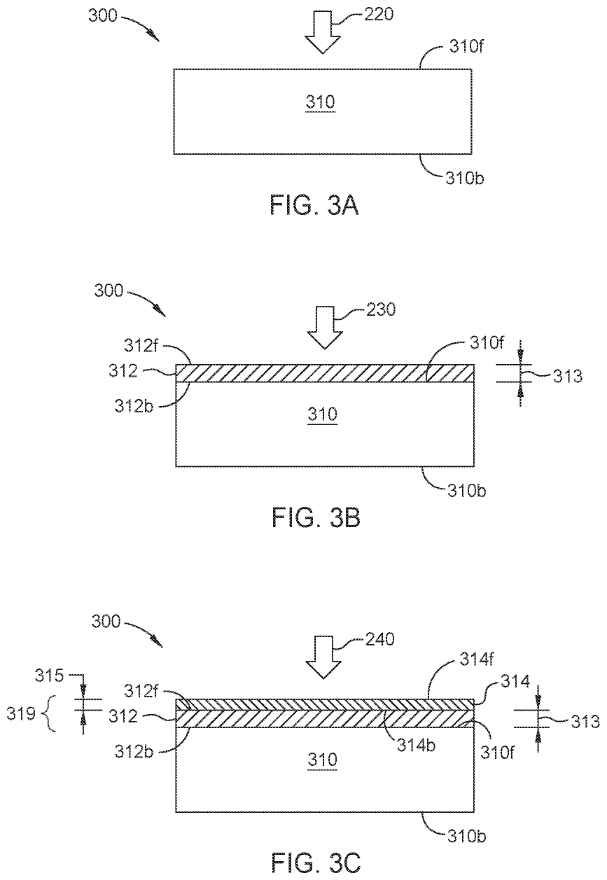

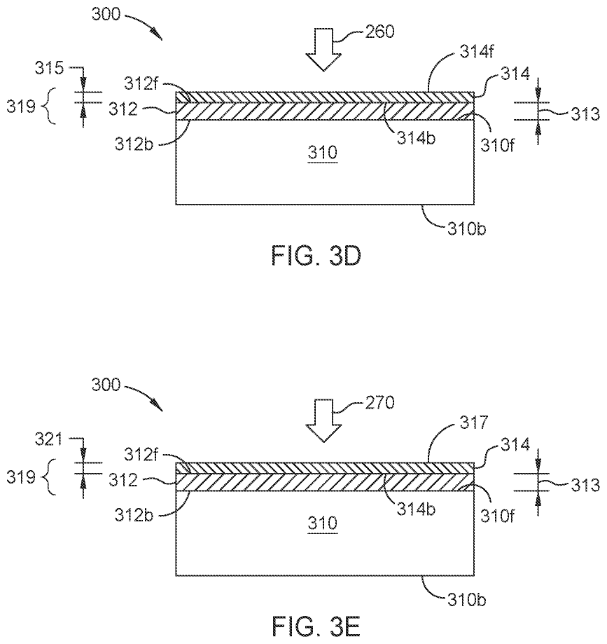

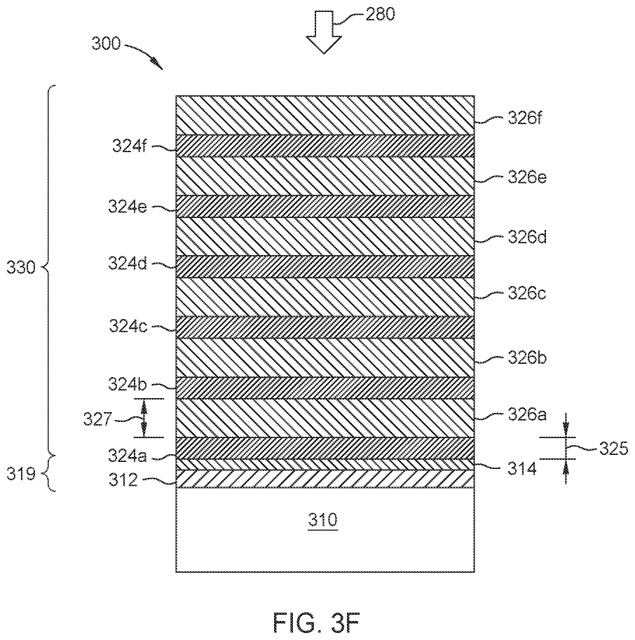

With reference to FIGS. 3A-3F, cross-sectional views of some embodiments of a device structure for semiconductor devices at various stages of manufacture are provided to illustrate the method 200 of FIG. 2. Although FIGS. 3A-3F are described in relation to the method 200, it will be appreciated that the structures disclosed in FIGS. 3A-3F are not limited to the method 200, but instead may stand alone as structures independent of the method 200. Similarly, although the method 200 is described in relation to FIGS. 3A-3F, it will be appreciated that the method 200 is not limited to the structures disclosed in FIGS. 3A-3F, but instead may stand alone independent of the structures disclosed in FIGS. 3A-3F.

At operation 210 of the method 200, a substrate is provided. The substrate may be a substrate 310, which is part of a semiconductor device structure 300 as is shown in FIGS. 3A-3F. In some embodiments, the substrate may be or include a bulk semiconductor substrate, a semiconductor-on-insulator (SOI) substrate, or the like. The term bulk semiconductor substrate refers to a substrate in which the entirety of the substrate is comprised of a semiconductor material. The bulk semiconductor substrate includes any suitable semiconducting material and/or combinations of semiconducting materials for forming a semiconductor structure. For example, the semiconducting layer may comprise one or more materials such as crystalline silicon (e.g., Si(100), Si(110), or Si(111)), silicon oxide, strained silicon, silicon germanium, doped or undoped polysilicon, doped or undoped silicon substrates, patterned or non-patterned substrates, doped silicon, germanium, gallium arsenide, or other suitable semiconducting materials. In some embodiments, the semiconductor material is silicon. In other embodiments, the semiconductor material is a doped material, such as n-doped silicon (n-Si), or p-doped silicon (p-Si). In some embodiments, the substrate includes additional materials, for example, a silicide layer, a metal silicide layer, a semiconductor layer, an etch stop layer (ESL), or a metal layer.

Referring to FIG. 3A, FIG. 3A illustrates a cross-sectional view of the semiconductor device structure 300 during intermediate stages of manufacturing corresponding to operations 210 and 220 of the method 200, in accordance with some embodiments. The semiconductor device structure 300 includes the substrate 310. The substrate 310 may be a substrate as described in operation 210. The substrate 310 has a frontside surface 310f (also referred to as a front surface) and a backside 310b (also referred to as a back surface) opposite the frontside surface 310f.

At operation 220 of the method 200, in some embodiments, the substrate 310 may be exposed to an optional pre-clean or surface treatment process. In some embodiments, the substrate 310 undergoes a surface treatment to improve mobility and bias temperature instability (BTI). In some embodiments, the surface treatment includes annealing the substrate 310 in an atmosphere of hydrogen (H2). The anneal process may be any suitable anneal process known to the skilled artisan. In some embodiments, the annealing is a rapid thermal process (RTP) anneal. In some embodiments, the anneal process is conducted at a temperature in a range of from about 500 degrees Celsius to about 900 degrees Celsius, or in a range of from about 600 degrees Celsius to about 900 degrees Celsius, or in a range of from about 600 degrees Celsius to about 800 degrees Celsius. In some embodiments, the anneal process is conducted at a pressure in a range of from about 5 Torr to about 20 Torr.

Next, as shown in FIG. 3B and FIG. 3C, a strain relaxed buffer (SRB) layer 319 is formed over the frontside surface 310f of the substrate 310.

FIGS. 3B and 3C illustrate cross-sectional views of the semiconductor device structure 300 during intermediate stages of manufacturing corresponding to operations 230 and 240 of the method 200, in accordance with some embodiments. As depicted in FIG. 3C, the SRB layer 319 is formed over the frontside surface 310f of the substrate. The SRB layer 319 may include any material that helps accommodate the lattice mismatch between the substrate 310 and the subsequently formed superlattice structure 330 (see FIG. 3F). The SRB layer 319 may be a multi-layer structure. In some embodiments as shown in FIG. 3C, the SRB layer 319 includes a first material layer 312 having a graded concentration of at least one component (e.g., germanium) and a second material layer 314 or capping layer having a uniform or substantially uniform concentration of the at least one component.

In some embodiments, operation 230 includes operation 240 and operation 250. In some embodiments, during operation 230 a first portion of the SRB layer 319, for example, the first material layer 312, is formed and during operation 240, a second portion of the SRB layer 319, for example, the second material layer 314 or capping layer, is formed. In some embodiments, the first material layer 312 is a silicon germanium (SiGe) layer having a germanium concentration gradient. The germanium concentration gradient may increase from a bottom surface of the SiGe layer to a top surface of the SiGe layer. In some embodiments, at operation 250, a capping layer, for example, a SiGe capping layer having a uniform or substantially uniform germanium concentration is formed on the SiGe layer having the germanium concentration gradient. It should be understood that although the first material layer 312 is depicted as a single layer, multiple layers may be used to form the germanium concentration gradient.

Turning to FIG. 3B, the first material layer 312 has a backside surface 312b and a frontside surface 312f (also referred to as a front surface) opposite the backside surface 312b (also referred to as a back surface). The backside surface 312b contacts the frontside surface 310f of the substrate 310. The first material layer 312 has a germanium concentration gradient. The germanium concentration gradient may increase from the backside surface 312b of the first material layer 312 to the frontside surface 312f of the first material layer 312. The first material layer 312 may be a SiGe spacer layer.

The first material layer 312 has a thickness 313. In some embodiments, the thickness 313 is in a range from about 1000 nm to about 5000 nm, or in a range from about 1500 nm to about 4000 nm, or in a range from about 1500 nm to about 3500 nm, or in a range from about 2000 nm to about 2500 nm, for example about 2000 nm.

Turning to FIG. 3C, the second material layer 314 has a backside surface 314b (also referred to as a back surface) and a frontside surface 314f (also referred to as a front surface) opposite the backside surface 314b. The backside surface 314b contacts the frontside surface 312f of the first material layer 312. The second material layer 314 has a uniform or substantially uniform concentration. The uniform or substantially uniform germanium concentration may be equal to, substantially equal to, or greater than a maximum germanium concentration of the germanium concentration gradient.

The second material layer 314 has a thickness 315. In some embodiments, the thickness 315 is in a range from about 500 nm to about 2000 nm, or in a range from about 800 nm to about 1500 nm, or in a range from about 800 nm to about 1200 nm, or in a range from about 1000 nm to about 1200 nm, for example about 1000 nm.

In some embodiments, the first material layer 312 and/or the second material layer 314 of the SRB include Group IV materials, such as silicon and germanium (e.g., Si₁₋ₓGeₓ, where x is germanium concentration). In some embodiments, the concentration (atomic percent) of germanium in the first material layer 312 may be graded. For example, the concentration of germanium may lowest near the interface with frontside surface 310f of the substrate 310 (e.g., near the backside surface 312b of the first material layer 312) and increase to be highest near the interface with the backside surface 314b of the second material layer 314 (e.g., the frontside surface 312f of the first material layer 312). For example, in some embodiments, the first material layer 312 is a SiGe layer having a graded germanium concentration, wherein the germanium concentration at an interface of the frontside surface 310f of the substrate 310 and the backside surface 312b of the first material layer 312 is similar to a germanium concentration of the substrate 310 (e.g., 0 at %), a germanium concentration at an interface of the frontside surface 312f of the first material layer and the backside surface 314b of the second material layer 314 (e.g., 10-15 at %) is similar to a uniform or substantially uniform germanium concentration of the second material layer 314 (e.g., 10-15 at %), and the uniform or substantially uniform germanium concentration of the second material layer 314 is similar to a germanium concentration of an adjacent SiGe layer in the superlattice structure (e.g., 10-15 at %).

In some embodiments, the graded germanium concentration of the first material layer 312 has a germanium content that increases in a range from about 0% to about 20%, or in a range from about 0% to about 15%, or in a range from about 0.1% to about 15%, or in a range from about 0.5% to about 15%, or in a range from about 1% to about 15%, or in a range from about 1% to about 10%. The silicon content of the first material layer 312 may be in a range from about 80% to about 100%, or in a range from about 85% to about 100%, or in a range from about 85% to about 99.9%, or in a range from about 85% to about 99.5%, or in a range from about 90% to about 99%. The first material layer 312 may have a maximum germanium content that is equal to or less than 10%, that is equal to or less than 15%, or that is equal to or less than 20%.

In some embodiments, the second material layer 314 or capping layer has a germanium content that is substantially equal to, equal to, or greater than the graded germanium concentration of the first material layer 312. The second material layer 314 may have a germanium content that is equal to or greater than 10%, that is equal to or greater than 15%, or that is equal to or greater than 20%. The second material layer 314 may have a germanium content that is in a range from about 10% to about 50%, or in a range from about 10% to about 30%, or in a range from about 10% to about 20%, or in a range from about 10% to about 15%, or in a range from about 15% to about 30%, or in a range from about 15% to about 20%. The silicon content of the second material layer 314 may be in a range from about 50% to about 90%, or in a range from about 70% to about 90%, or in a range from about 80% to about 90%, or in a range from about 85% to about 90%, or in a range from about 70% to about 85%, or in a range from about 80% to about 85%.

In particular embodiments, the first material layer 312 is a SiGe layer having a thickness in a range from about 2000 nm to about 2500 nm and a graded concentration of germanium which increases from a first germanium concentration in a range from about at % to about 2 at %) adjacent to an interface with the substrate 310, for example, a silicon substrate and increases to a second germanium concentration or maximum germanium concentration, for example, in a range from about 10 at % to about 15 at %, adjacent to an interface with the first material layer 312 and the second material layer 314 is a SiGe capping layer having a thickness in a range from about 1000 nm to about 1200 nm and having a substantially uniform concentration that is substantially equal to, equal to, or greater than the maximum germanium concentration of the graded germanium concentration of the first material layer 312.

In some embodiments, the first material layer 312 and the second material layer 314 are formed via an epitaxial chemical vapor deposition process. The epitaxial deposition process provides for precise control of the germanium content in each of the first material layer 312 and the second material layer 314, which provides advantageous control of lattice matching with either the underlying substrate 310 or the subsequently deposited superlattice structure. In some embodiments, the epitaxial deposition process includes loading a substrate, for example, the substrate 310, into a deposition chamber, for example, the deposition chamber 100, and adjusting the conditions within the deposition chamber to a targeted temperature and pressure. Then, a deposition process is initiated to form one or more epitaxial layers on a monocrystalline surface of the substrate. The deposition process is then terminated. The thickness of the epitaxial layer is then determined. If the predetermined thickness of the epitaxial layer is achieved, then the epitaxial process is terminated. However, if the predetermined thickness is not achieved, then the epitaxial process may continue until the predetermined thickness is achieved. Further details of this exemplary process are described below.

After loading a substrate into the process chamber, for example, the deposition chamber 100, the conditions in the deposition chamber are adjusted to a predetermined temperature and pressure. The temperature is tailored to the particular conducted process. The appropriate temperature to conduct the epitaxial process may depend on the particular precursors used to deposit the silicon-containing and silicon-germanium containing materials. In some embodiments, the process chamber and/or substrate is maintained at a temperature equal to or greater than 900 degrees Celsius, or at a temperature greater than or equal to 1000 degrees Celsius, or at a temperature greater than or equal to 1100 degrees Celsius, or at a temperature greater than or equal to 1200 degrees Celsius. In some embodiments, the process chamber and/or substrate is maintained at a temperature in a range from about 900 degrees Celsius to about 1200 degrees Celsius, or in a range from about 900 degrees Celsius to about 1100 degrees Celsius, or in a range from about 1000 degrees Celsius to about 1100 degrees Celsius during the epitaxial deposition process. Not to be bound by theory, but in some implementations where the deposition process is performed at a higher temperature, for example, 1000 degrees Celsius or greater, the higher temperature during deposition obviates the need for a subsequent anneal process. In some embodiments, the SRB In some embodiments, the process chamber is maintained at a pressure in a range from about 10 mTorr to about 50 Torr, or in a range from about 1 Torr to about 20 Torr, or in a range from about 5 Torr to about 10 Torr during epitaxial deposition process. The pressure may fluctuate during and between processes, but is generally maintained constant.

During the epitaxial deposition process the substrate 310 is exposed to a deposition gas to form the first material layer 312 and the second material layer 314. In some embodiments, the substrate 310 is exposed to the deposition gas for a period of time in a range from about 0.5 seconds to about 30 seconds, or in a range from about 1 second to about 20 seconds, or in a range from about 5 seconds to about 10 seconds. In particular embodiments, the deposition process lasts for about 10 to 11 seconds. The specific exposure time during the epitaxial deposition process is generally related to the particular precursors and temperature used in the epitaxial deposition process. Generally, the substrate is exposed to the deposition gas long enough to form a targeted thickness of the epitaxial layers in the SRB layer 319.

In some embodiments, the deposition gas contains at least a silicon source, and may contain a carrier gas and/or at least one secondary elemental source, such as a germanium source and/or a carbon source.

In some embodiments, the silicon source is usually provided into the process chamber at a rate in a range from about 5 sccm to about 500 sccm, or in a range from about 10 sccm to about 300 sccm, or in a range from about 50 sccm to about 200 sccm, for example, about 100 sccm. Silicon sources useful in the deposition gas to deposit silicon-containing compounds include silanes, halogenated silanes, and organosilanes. Silanes include silane (SiH₄) and higher silanes with the empirical formula SiₓH₍₂ₓ₊₂₎, such as disilane (Si₂H₆), trisilane (Si₃H₈), tetrasilane (Si₄H₁₀), and neopentasilane, as well as others. Halogenated silanes include compounds with the empirical formula X_{y}SiₓH_{(2x+2-y)}, where X′=F, Cl, Br or I, such as hexachlorodisilane (Si₂Cl₆), tetrachlorosilane (SiCl₄), dichlorosilane (Cl₂SiH₂) and trichlorosilane (Cl₃SiH). Organosilanes include compounds with the empirical formula R_{y}SiₓH_{(2x+2-y)}, where R=methyl, ethyl, propyl or butyl, such as methylsilane ((CH₃)SiH₃), dimethylsilane ((CH₃)₂SiH₂), ethylsilane ((CH₃CH₂)SiH₃), methyldisilane ((CH₃)Si₂H₅), dimethyldisilane ((CH₃)₂Si₂H₄) and hexamethyldisilane ((CH₃)₆Si₂). Organosilane compounds have been found to be advantageous silicon sources as well as carbon sources in embodiments which incorporate carbon in the deposited silicon-containing compound.

In some embodiments where the silicon source is provided with a carrier gas, the carrier gas has a flow rate in a range from about 1 slm (standard liters per minute) to about 100 slm, or in a range from about 5 slm to about 75 slm, or in a range from about 10 slm to about 50 slm, or in a range from about 10 slm to about 20 slm. Carrier gases may include nitrogen (N₂), hydrogen (H₂), argon, helium, or a combination thereof. In some embodiments, an inert carrier gas is preferred and is selected from nitrogen, argon, helium, or a combination thereof. A carrier gas may be selected based on the precursor(s) used and/or the process temperature during the epitaxial process.

In some embodiments, the deposition gas used also contains at least one secondary elemental source, such as a germanium source and/or a carbon source. The germanium source may be added to the process chamber with the silicon source and optionally the carrier gas to form a silicon-containing compound, such as a silicon germanium material layer. In some embodiments, the germanium source is provided into the process chamber at a rate in a range from about 0.1 sccm to about 20 sccm, for example, in a range from about 0.5 sccm to about 10 sccm, or in a range from about 1 sccm to about 5 sccm. In some embodiments, the flow rate of the germanium source can be varied or increased during deposition of the first material layer 312 to form the increasing germanium concentration gradient. Germanium sources useful to deposit silicon-containing compounds include germane (GeH₄), higher germanes and organogermanes. Higher germanes include compounds with the empirical formula GeₓH₍₂ₓ₊₂₎, such as digermane (Ge₂H₆), trigermane (Ge₃H₈), and tetragermane (Ge₄H₁₀), as well as others. Organogermanes include compounds such as methylgermane ((CH₃)GeH₃), dimethylgermane ((CH₃)₂GeH₂), ethylgermane ((CH₃CH₂)GeH₃), methyldigermane ((CH₃)Ge₂H₅), dimethyldigermane ((CH₃)₂Ge₂H₄) and hexamethyldigermane ((CH₃)₆Ge₂). Germanes and organogermane compounds have been found to be advantageous germanium sources and carbon sources in embodiments while incorporating germanium and carbon into the deposited silicon-containing compounds, namely SiGe and SiGe:C compounds. In some embodiments, the germanium concentration in the epitaxial layer is in the range from about 1 atomic % to about 30 atomic %, for example, about 20 atomic %. In some embodiments, the germanium concentration may be graded within an epitaxial layer as discussed herein.

A carbon source may be added during deposition to the process chamber with the silicon source and/or germanium source, and optionally the carrier gas to form a silicon-containing compound, such as a silicon carbon material (e.g., Si:C) or a silicon germanium carbon material (e.g., SiGe:C). In some embodiments, the carbon source is provided into the process chamber at a rate in a range from about 0.1 sccm to about 40 sccm, or in a range from about 3 sccm to about 25 sccm, or in a range from about 5 sccm to about 25 sccm. The carbon source may be 5% diluted in argon or nitrogen gas and flowed at a rate of 750 sccm. Carbon sources useful to deposit silicon-containing compounds include organosilanes, alkyls, alkenes and alkynes of ethyl, propyl and butyl. Such carbon sources include methylsilane (CH₃SiH₃), dimethylsilane ((CH₃)₂SiH₂), ethylsilane (CH₃CH₂SiH₃), methane (CH₄), ethylene (C₂H₄), ethyne (C₂H═), propane (C₃H₈), propene (C₃H₆), butyne (C₄H₆), as well as others. In some embodiments, the carbon concentration of an epitaxial layer is in the range from about 200 ppm to about 5 atomic %, or in a range from about 1 atomic % to about 3 atomic %. In some embodiments, the carbon concentration may be graded within an epitaxial layer, preferably graded with a lower carbon concentration in the initial portion of the epitaxial layer than in the final portion of the epitaxial layer. Alternatively, a germanium source and a carbon source may both be added during deposition into the process chamber with the silicon source and carrier gas to form a silicon-containing compound, such as a silicon carbon or silicon germanium carbon material.

In a particular embodiment, the first material layer 312, which may be an epitaxial SiGe layer with a graded germanium concentration, and the second material layer 314, which may be an epitaxial SiGe layer having uniform or substantially uniform germanium concentration is formed using either DCS or TCS as the silicon source gas and GeH₄ or GeCl₄ as the germanium source gas. Using DCS or TCS as the silicon source gas provides for a high growth rate process with chlorine-surface termination, which leads to excellent interfacial abruptness. This interfacial abruptness contributes to improved etch selectivity of the SiGe SRB layers relative to the layers of the superlattice structure. In addition, using DSC or TCS enables deposition of the first material layer 312, the second material layer 314, or both the first material layer 312 and the second material layer 314 at higher deposition temperatures, for example, at deposition temperatures of 900 degrees Celsius or higher.

In some embodiments, after the deposition process of operation 240 and operation 250 are terminated, the process chamber may be flushed with a purge gas or the carrier gas and/or the process chamber may be evacuated with a vacuum pump. The purging and/or evacuating processes remove excess deposition gas, reaction by-products and other contaminants. In some embodiments, the process chamber may be purged in between deposition of the first material layer 312 and the second material layer 314. In one embodiment, the process chamber may be purged for about 10 seconds by flowing a carrier gas at about 5 slm. A cycle of deposition and purge may be repeated for numerous cycles.

In some embodiments, the SRB layer 319 may be exposed to a heating or rapid heating process to relax the SRB layer 319. The heating or rapid heating process may occur in between operation 240 and operation 250, after operation 250, or both in between operation 240 and operation 250 and after operation 250. To ensure full relaxation in a controlled, repeatable manner, the use of thermal processes such as rapid thermal processing (RTP), soak anneals, spike anneals, millisecond anneals and nanosecond anneals (in sub-melt or melt time-temperature regimes) are contemplated.

In some embodiments, operation 240 and operation 250 are integrated such that there is no vacuum break between operation 240 and operation 250. For example, operation 240 and operation 250 may be performed in the same processing chamber, for example, the deposition chamber 100. In some embodiments, operation 240 and operation 250 are performed in separate processing chamber which are integrated on the same platform such that there is no vacuum break, for example, the cluster tool 500.

At operation 260, the SRB layer 319 may be exposed to a planarization process. In some embodiments, the frontside surface 314f of the second material layer 314 or capping layer of the SRB layer 319 has high surface roughness. This high surface roughness of frontside surface 314f of the SRB layer 319 makes it challenging to use the SRB layer 319 as a template for subsequent growth of the superlattice structure 330 on the SRB layer 319. The planarization process of operation 260 removes a portion of the frontside surface 314f of the second material layer 314 or capping layer to form a smoothed surface 317 and expose the pristine surface underneath. In some embodiments, the smoothed surface 317 has a root mean square (RMS) roughness of 20 Å or less, of 10 Å or less, or of 5 Å or less, or of 3 Å or less. During operation 260, any suitable planarization process may be used. The planarization process may be a chemical mechanical polishing (CMP) process. In some embodiments, after the planarization process, the second material layer 314 or capping layer of the SRB layer 319 may have a reduced thickness 321 relative to the thickness 315, as is shown in FIG. 3E, in a range from about 200 nm to about 1700 nm, or in a range from about 500 nm to about 1200 nm, or in a range from about 500 nm to about 900 nm, or in a range from about 700 nm to about 900 nm, for example about 700 nm. In some embodiments, the reduced thickness 321 of the second material layer 314 or capping layer by about 40% or less, by about 30% or less, by about 20% or less, for example, in a range from about 10% to about 30% relative to the thickness 315.

In some embodiments, a vacuum break occurs in between operations 230 where the SRB layer 319 is formed and operation 260, where the SRB layer 319 is planarized. This vacuum break can lead to the formation of oxides on the SRB. In addition, the planarization process may lead to the formation of additional contaminants or debris on the surfaces of the SRB layer 319. Thus, it may be appropriate to clean the SRB layer 319 prior to forming the superlattice structure on the SRB layer 319 at operation 280.

At operation 270, the SRB layer 319 may be exposed to one or more cleaning processes prior to forming the superlattice structure 330 on the SRB layer 319. The one or more cleaning processes of operation 270 may include one or more of a wet clean process and a dry clean process. The wet clean process may be, for example, a standard clean-1 (SC-1) process, a standard clean-2 (SC-2) process, and/or a HF process. The dry clean process may include a plasma etch process, such as a two-process dry chemical clean process using NF₃ and NH₃. In some embodiments, operation 270 includes one or more wet clean processes followed by one or more dry clean processes.

In some embodiments, the SRB layer 319 is exposed to a wet clean process prior to formation of the superlattice structure 330 on the SRB layer 319. The wet clean process may be used to remove oxides or other contaminants from the SRB layer 319 after the planarization process of operation 260. The wet clean process may be a SC-1 process, a SC-2 process, HF-first process, a HF-last process, or a combination thereof. The wet clean process may include an acidic cleaning process (e.g., a solution containing hydrochloric acid and hydrogen peroxide held at elevated temperature, such as SC-2 process), a basic cleaning process (e.g., a solution containing ammonium hydroxide and hydrogen peroxide held at elevated temperature, such as SC-1 clean), or a series of wet cleans containing both acidic and basic cleaning processes. In particular embodiments, the SRB layer 319 is exposed to a SC-1 solution (e.g., TMAH and H₂O₂) to remove organic residues and other contaminants and subsequently, exposed to a SC-2 solution (e.g., H₂O₂ and HCl) to remove native oxides.

In some embodiments, the oxides and/or contaminants on the smoothed surface 317 of the second material layer 314 or capping layer of the SRB layer 319 may be removed by the HF-first process or the HF-last process. In one example, the wet-clean process utilizes an HF-first or HF-last solution containing water, HF and optional additives including chelators, surfactants, reductants, other acids or combinations thereof. In one example, the hydrogen fluoride concentration of a wet-clean solution may be within a range from about 10 ppm to about 5 wt. %, or from about 50 ppm to about 2 wt. %, or from about 100 to about 1 wt. %, for example, about 0.5 wt. %.

In some embodiments, the SRB layer 319 may be exposed to a SC-1 clean solution during operation 270 to remove contaminants, such as organic and inorganic residues and particulates from the SRB layer 319. In one example, the SC-1 clean solution contains hydrogen peroxide and at least one basic compound, such as ammonium hydroxide, tetramethylammonium hydroxide, ethanolamine, diethanolamine, triethanolamine, derivatives thereof, salts thereof, or a combination thereof. During the SC-1 clean, the substrate 310 may be heated to a temperature within a range from about 50 degrees Celsius to about 100 degrees Celsius or in a range from about 70 degrees Celsius to about 90 degrees Celsius.

In some embodiments, the SRB layer 319 may be exposed to a SC-2 clean solution during operation 270. In one example, the SC-2 clean solution contains hydrogen peroxide and hydrogen chloride. During the SC-2 clean, the substrate 310 may be heated to a temperature within a range from about 50 degrees Celsius to about 100 degrees Celsius or in a range from about 70 degrees Celsius to about 90 degrees Celsius.

In particular embodiments, the SRB layer 319 is exposed to HF followed by a SC-1 and/or SC-2 clean solution.

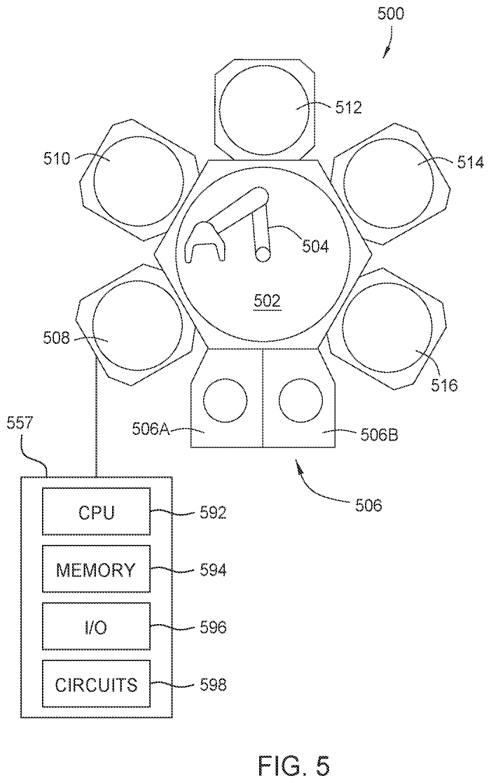

In some embodiments, the SRB layer 319 is exposed to a dry clean process and/or a degas process prior to formation of the superlattice structure 330 on the SRB layer 319. The SRB layer 319 may be exposed to a dry clean process and/or a degas process after the wet clean process and prior to formation of the superlattice structure 330 on the SRB layer 319. The dry clean process may be used to remove oxides from the surface of the SRB layer 319. In some embodiments the wet-clean process is performed ex-situ to the cluster tool 500, the SRB layer 319 may be subjected to a dry clean and/or degas process upon entering the cluster tool 500. For example, if the SRB layer 319 includes silicon, the Applied Materials SICONI™ clean processes may be performed on the SRB layer 319 for removing oxide from the formed SRB layer 319. The SICONI™ clean process removes native oxide through a low-temperature, two-process dry chemical clean process using NF₃ and NH₃. The clean process may be performed in a processing chamber positioned on a cluster tool, for example, the cluster tool 500 (see FIG. 5). Exemplary pre-clean chambers in which the dry clean process of operation 270 may be performed include SICONI™ clean chamber available from Applied Materials, Inc., of Santa Clara, Calif.

In some embodiments, the SRB layer 319 may be exposed to a fluorine-containing precursor and a hydrogen-containing precursor in a two-part dry chemical clean process. In some embodiments, the fluorine-containing precursor may include nitrogen trifluoride (NF₃), hydrogen fluoride (HF), diatomic fluorine (F₂), monatomic fluorine (F), fluorine-substituted hydrocarbons, combinations thereof, or the like. In some embodiments, the hydrogen-containing precursors may include atomic hydrogen (H), diatomic hydrogen (H₂), ammonia (NH₃), hydrocarbons, incompletely halogen-substituted hydrocarbons, combinations thereof, or the like.

In some embodiments, the first part in the two part dry clean process may include using a remote plasma source to generate an etchant species (e.g., ammonium fluoride (NHF₄)) from the fluorine-containing precursor (e.g., nitrogen trifluoride (NF₃)) and the hydrogen-containing precursor (e.g., ammonia (NH₃)). By using a remote plasma source, damage to the SRB layer 319 may be minimized. The etchant species may then be introduced into the pre-clean chamber and condensed into a solid by-product on the surface of the SRB layer 319 through a reaction with the native oxide layer. The second process may then include an in-situ anneal to decompose the by-product using convection and radiation heating. The by-product then sublimates and may be removed from the surface of the SRB layer 319 via a flow of gas and pumped out of the pre-clean chamber.

In some embodiments, the SRB layer 319 is exposed to a surface treatment process prior to formation of the superlattice structure 330 on the SRB layer 319. The SRB layer 319 may be exposed to the surface treatment process after the dry clean process and/or the wet clean process and prior to formation of the superlattice structure 330 on the SRB layer 319. In some embodiments, the surface treatment includes annealing the SRB layer 319 in an atmosphere of hydrogen (H₂). The anneal process may be any suitable anneal process known to the skilled artisan. In some embodiments, the annealing process includes a rapid thermal process (RTP) anneal. In some embodiments, the anneal process is conducted at a temperature in a range of from about 500 degrees Celsius to about 1000 degrees Celsius, or in a range of from about 600 degrees Celsius to about 900 degrees Celsius, or in a range of from about 600 degrees Celsius to about 800 degrees Celsius. In some embodiments, the anneal process is conducted at a pressure in a range of from about 10 mTorr to about 30 Torr, or in a range from about 5 Torr to about 20 Torr, or in a range from about 5 Torr to about 10 Torr.

At operation 280, a superlattice structure 330 is formed on the SRB layer 319. The term superlattice, as utilized herein, generally refers to a stack of material layers, which are closely lattice matched materials, but are sufficiently different in composition that selective removal processes can be performed on the superlattice structure 330. More generally, the composition of various material layers in the stack may be unique to one or more of the materials layers in the stack. In one example, the superlattice structure 330 includes one or more layers of a silicon-containing material (e.g., Si) and a silicon germanium containing material (e.g., SiGe). In some embodiments, the superlattice structure 330 includes a first material layer and a second material layer. In some embodiments, the superlattice structure 330 includes a first material layer, a second material layer, a third material layer, and a fourth material layer. In this embodiment, the second material layer, the third material layer, and the fourth material layer are formed from the same compound material, but may have different material properties.

Forming the superlattice structure 330 at operation 280 includes forming a first material layer and forming a second material layer on the first material layer. Forming the first material layer and forming the second material layer may be repeated until the superlattice structure achieves a targeted thickness and/or number of layers. The first material layer and the second material layer may be alternatingly arranged in stacked pairs. The superlattice structure 330 may include a plurality of first material layers 324a-f (collectively 324) and a corresponding plurality of second material layers 326a-f (collectively 326) alternatingly arranged in a plurality of stacked pairs. In one embodiment, the plurality of first material layers 324a-f are formed from at least a silicon-containing material and a germanium-containing material and the plurality of second material layers 326a-f are formed from a silicon-containing material. In some embodiments, the plurality of first material layers 324a-f are SiGe spacer layers and the plurality of second material layers 326a-f are silicon channel layers. Accordingly, the first material layer and the second material layer are different materials. In some embodiments, the plurality of first material layers 324a-f and corresponding plurality of second material layers 326a-f are lattice matched materials with a sufficient difference in composition such that selective layer removal can subsequently be performed.

In some embodiments, the plurality of first material layers 324a-f include Group IV materials, such as silicon and germanium (e.g., SiGe). The plurality of second material layers 326a-f include Group IV materials, such as silicon (e.g., Si). In some embodiments, the silicon germanium layers have a silicon:germanium molar ratio of between about 1:1 and about 5:1. In some embodiments, the silicon germanium layers have a germanium content in a range from about 10% to about 50%, or in a range from about 20% to about 50%, or in a range from about 20% to about 40%, or in a range from about 30% to about 40%. The silicon content may be in a range from about 50% to about 90%, or in a range from about 50% to about 80%, or in a range from about 60% to about 80%, or in a range from about 60% to about 70%. In other embodiments, the silicon germanium layers have a germanium content in a range from about 20% to about 90%, or in a range from about 50% to about 80%. The silicon content may be in a range from about 10% to about 80%, or in a range from about 20% to about 50%.

In some embodiments, the plurality of first material layers 324a-f and corresponding plurality of second material layers 326a-f may be any number of lattice matched material pairs suitable for forming the superlattice structure 330. For example, the plurality of first material layers 324a-f and corresponding plurality of second material layers 326a-f include between about 2 to about 100 pairs of lattice matched materials, for example, 6 pairs of lattice matched materials as is shown in FIG. 3F.

The material layers of the superlattice structure 330 may have controlled thicknesses to provide for substantially defect free crystallographic profiles of the various materials. In some embodiments, the layers of the superlattice structure 330 have a total thickness in a range from about 3 nm to about 50 nm, or in a range from about 5 nm to about 40 nm, or in a range from about 5 nm to about 30 nm, or in a range from about 5 nm to about 20 nm. In some embodiments, the layers of the superlattice structure 330 have a thickness in a range from about 3 nm to about 50 nm. For example, the plurality of first material layers 324a-f may have a thickness 325 in a range from about 1 nm to about 20 nm or, or in a range from about 1 nm to about 10 nm, or in a range from about 3 nm to about 10 nm, or in a range from about 5 nm to about 7 nm, for example, about 6 nm. The plurality of second material layers 326a-f may have a thickness 327 in a range from about 1 nm to about 20 nm, or in a range from about 5 nm and about 15 nm, or in a range from about 7 nm to about 10 nm, for example, about 8 nm.

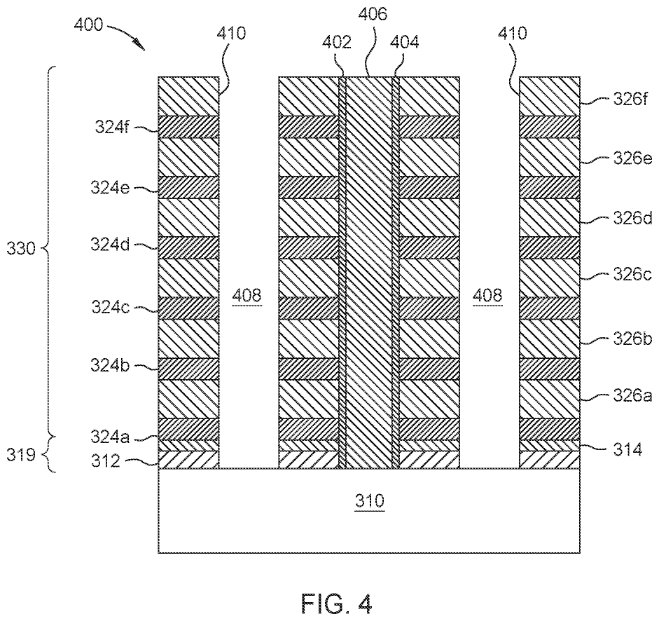

FIG. 4 illustrates a partial device structure 400 of a memory device. The partial device structure 400 may be formed from the semiconductor device structure 300. A similar device structure may be formed from a different super-lattice structure. The partial device structure 400 includes a plurality of trenches 408 formed through the plurality of first material layers 324a-f and the plurality of second material layers 326a-f of the superlattice structure 330 and the first material layer 312 and the second material layer 314 or capping layer of the SRB layer 319. The trenches 408 include sidewalls 410 which may be etched or treated during later process operations. The partial device structure 400 further includes a plurality of etch-holes 402, which may be similar to the trenches 408. However, the etch-holes 402 have been filled with one or more of a poly material 404 and an oxide material 406. The poly material 404 may be a polycrystalline silicon material. The oxide material 406 may be a silicon oxide or a silicon nitride. In some embodiments, the oxide material 406 may instead be a silicon-germanium material.

The partial device structure 400 is illustrated herein as an exemplary structure which may be formed from the superlattice structure 330 and the SRB layer 319. It is contemplated a variety of device structures may be formed from the superlattice structure 330 and the SRB layer 319 using the methods described herein.

FIG. 5 is a plan view of a cluster tool 500 according to another embodiment described herein. The cluster tool 500 features at least one epitaxial deposition chamber, as described above. An example of the cluster tool 500 is the CENTURA® system available from Applied Materials, Inc., of Santa Clara, California. Cluster tools manufactured by others may be used as well. A transfer robot 504 of any convenient type is disposed in a transfer chamber 502 of the cluster tool 500. A load-lock 506, with two load-lock chambers 506A, 506B is coupled to the transfer chamber 502. A plurality of processing chambers 508, 510, 512, 514, and 516 are also coupled to the transfer chamber 502. The plurality of processing chambers 508, 510, 512, 514, and 516 may include at least one of: a pre-clean chamber, a material deposition chamber such as an epitaxial deposition chamber, for example, the deposition chamber 100, and a thermal processing chamber, such as an anneal, degas, or oxidation chamber.

Processing chamber 508 may be a pre-clean chamber configured to clean the substrate prior to deposition of a strain relaxed buffer layer and/or superlattice structure. The pre-clean chamber may be configured to perform the Applied Materials SICONI™ Pre-clean process. Processing chamber 510 and/or 514 may be a material deposition chamber such as an epitaxial deposition chamber capable of performing an epitaxial growth process. Processing chamber 512 and/or 516 may be additional material deposition chamber or a thermal treatment chamber capable of performing a thermal treatment process.

A system controller 557 is in communication with the transfer robot 504, and the plurality of processing chambers 508, 510, 512, 514, and 516. The system controller 557 can be any suitable component that can control the processing chambers and robots. For example, the system controller 557 can be a computer including a central processing unit (CPU) 592, memory 594, inputs/outputs 596, suitable circuits 598, and storage.

Processes may generally be stored in the memory of the system controller 557 as a software routine that, when executed by the processor, causes the process chamber to perform processes of the present disclosure. The software routine may also be stored and/or executed by a second processor (not shown) that is remotely located from the hardware being controlled by the processor. Some or all of the method of the present disclosure may also be performed in hardware. As such, the process may be implemented in software and executed using a computer system, in hardware as, e.g., an application specific integrated circuit or other type of hardware embodiment, or as a combination of software and hardware. The software routine, when executed by the processor, transforms the general-purpose computer into a specific purpose computer (controller) that controls the chamber operation such that the processes are performed.

In some embodiments, the system controller 557 has a configuration to control the epitaxial growth chamber to grow a strain relaxed buffer, for, example the SRB layer 319.

The cluster tool 500 may be used to perform the method 200 described above. During processing, a substrate that is to be processed may arrive to the cluster tool 500 in a pod (not shown). The substrate is transferred from the pod to the vacuum compatible load-lock chambers 506A, 506B by the factory interface robot (not shown). The substrate is then picked by the transfer robot 504 in the transfer chamber 502 which is generally kept in a vacuum state. The transfer robot 504 then loads the substrate into the processing chamber 508 for cleaning as described in operation 220. The transfer robot 504 then picks up the substrate from the processing chamber 508 and loads the substrate into the processing chamber 510 or 514, whichever is available, for epitaxial deposition. An epitaxial strain relaxed buffer layer as described herein may be grown on the cleaned substrate in the processing chamber 510 or 514. The transfer robot 504 then picks up the substrate from the processing chamber 510 or 514 and transfers the substrate into the processing chamber 512 or 516, which are thermal processing chambers, whichever is available. The epitaxial buffer layer may then be exposed to a rapid heating/cooling process. The transfer robot 504 then picks the substrate from the processing chamber 512 or 516 and transfers the substrate to processing chamber 514 for deposition of active material over the buffer layer as described in operation 280.

In the Summary and in the Detailed Description, and the claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect or embodiment of the present disclosure, or a particular claim, that feature can also be used, to the extent possible in combination with and/or in the context of other particular aspects and embodiments of the present disclosure, and in the present disclosure generally.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or embodiment(s) thereof, the articles “a,” “an,” “the” and “said” are intended to mean that there are one or more of the elements.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

While the foregoing is directed to embodiments of the present disclosure, other and further embodiments of the disclosure may be devised without departing from the basic scope thereof, and the scope thereof is determined by the claims that follow.

1. A method of forming a strain relaxed buffer (SRB) layer on a substrate, comprising:
epitaxially depositing a first silicon germanium layer over the substrate, wherein the first silicon germanium layer has a first surface that contacts a frontside surface of the substrate and a second surface opposite the first surface, wherein the first silicon germanium layer has a first thickness and a germanium concentration gradient that increases from the first surface to the second surface; and
epitaxially depositing a silicon germanium capping layer on the first silicon germanium layer, wherein the silicon germanium capping layer has a second thickness and a substantially uniform germanium concentration that is equal to, substantially equal to, or greater than a maximum germanium concentration of the germanium concentration gradient.

2. The method of claim 1, wherein the first thickness is in a range from about 2000 nm to about 2500 nm and the germanium concentration gradient increases from 0 at % adjacent to an interface with the substrate to the maximum germanium concentration in a range from about 10 at % to about 15 at %.

3. The method of claim 2, wherein the second thickness is in a range from about 1000 nm to about 1200 nm and the substantially uniform germanium concentration is substantially equal to, equal to, or greater than the maximum germanium concentration of the first silicon germanium layer.

4. The method of claim 1, wherein the germanium concentration gradient increases from a first germanium concentration in a range from about 0 at % to about 2 at % of germanium to a second germanium concentration in range from about 10 at % to about at %.

5. The method of claim 1, wherein the substrate comprises silicon.

6. The method of claim 1, further comprising polishing the silicon germanium capping layer to reduce the second thickness to a third thickness.

7. The method of claim 1, wherein after polishing the silicon germanium capping layer, the silicon germanium capping layer has a top surface having a root mean square (RMS) roughness of 5 Å or less.

8. The method of claim 6, further comprising exposing the silicon germanium capping layer to a wet clean process after polishing the silicon germanium capping layer.

9. The method of claim 1, wherein epitaxially depositing the first silicon germanium layer over the substrate comprises increasing a flow rate of a germanium source gas to form the germanium concentration gradient that increases from the first surface to the second surface.

10. A device structure, comprising:
a substrate;
a strain relaxed buffer layer formed on the substrate, the strain relaxed buffer layer, comprising:
a first silicon germanium layer having a first surface that contacts a frontside surface of the substrate and a second surface opposite the first surface, wherein the first silicon germanium layer has a first thickness and a germanium concentration gradient that increases from the first surface to the second surface; and
a silicon germanium capping layer that contacts the second surface of the first silicon germanium layer and wherein the silicon germanium capping layer has a second thickness and a substantially uniform germanium concentration that is equal to, substantially equal to, or greater than a maximum germanium concentration of the germanium concentration gradient; and
a superlattice structure formed on the strain relaxed buffer layer, the superlattice structure comprising:
a silicon germanium spacer layer; and
a silicon channel layer, wherein the silicon germanium spacer layer and the silicon channel layer are disposed in an alternating stacked arrangement.

11. The device structure of claim 10, wherein the first thickness is in a range from about 2000 nm to about 2500 nm and the germanium concentration gradient increases from 0 at % adjacent to an interface with the substrate to a maximum germanium concentration in a range from about 10 at % to about 15 at %.

12. The device structure of claim 11, wherein the second thickness is in a range from about 1000 nm to about 1200 nm and the substantially uniform germanium concentration is substantially equal to, equal to, or greater than the maximum germanium concentration of the first silicon germanium layer.

13. The device structure of claim 10, wherein the germanium concentration gradient increases from a first germanium concentration in a range from about 0 at % to about 2 at % of germanium to a second germanium concentration in range from about 10 at % to about 15 at %.

14. The device structure of claim 10, wherein the device structure is a dynamic random-access memory (DRAM) device.

15. The device structure of claim 10, wherein the silicon germanium capping layer has a top surface having a root mean square (RMS) roughness of 5 Å or less.

16. The device structure of claim 10, further having a plurality of trenches formed through the strain relaxed buffer layer and the superlattice structure.

17. The device structure of claim 16, further having one or more etch-holes formed through the strained relaxed buffer and the superlattice structure, wherein the one or more etch-holes have been filled with one or more of a poly material and an oxide material.

18. The device structure of claim 17, wherein the poly material is a polycrystalline silicon material and the oxide material is silicon oxide.

19. The device structure of claim 10, wherein the substrate comprises silicon.

20. A method of forming a semiconductor device, comprising:
epitaxially depositing a strain relaxed buffer layer over a substrate, in a first processing chamber, comprising:
epitaxially depositing a first silicon germanium layer over the substrate, wherein the first silicon germanium layer has a first thickness and a germanium concentration gradient that increases from a first surface to a second surface of the first silicon germanium layer; and
epitaxially depositing a silicon germanium capping layer on the first silicon germanium layer, wherein the silicon germanium capping layer has a second thickness and a substantially uniform germanium concentration that is equal to, substantially equal to, or greater than a maximum germanium concentration of the germanium concentration gradient;
transferring the substrate to a second processing chamber positioned ex-situ to an integrated processing system;
polishing the silicon germanium capping layer to reduce the second thickness to a third thickness in the second processing chamber;
transferring the substrate to a third processing chamber positioned ex-situ to the integrated processing system;
exposing the silicon germanium capping layer to a wet clean process in the third processing chamber after polishing the silicon germanium capping layer;
transferring the substrate to a first processing chamber of the integrated processing system;
exposing the substrate to a dry clean process in the first processing chamber of the integrated processing system using a remote plasma source to generate an etchant species from a fluorine-containing precursor and a hydrogen-containing precursor;
transferring the substrate to a second processing chamber of the integrated processing system; and
epitaxially depositing a superlattice structure on the strain relaxed buffer layer in the second processing chamber of the integrated processing system.
